(19) United States
(12) Patent Application Publication
(10) Pub. No.: US 2015/0346249 A1
(43) Pub. Date: Dec. 3, 2015

(54) USAGE STATE DETECTION WITH AC-POWERED TAGS

(71) Applicant: Emanate Wireless, Inc., Ijamsville, MD (US)

(72) Inventor: Gary L. Sugar, Rolling Meadows, IL (US)

(21) Appl. No.: 14/722,406

(22) Filed: May 27, 2015

Related U.S. Application Data
(60) Provisional application No. 62/003,547, filed on May 28, 2014.

(51) Int. Cl. G01R 21/133

(52) U.S. Cl. CPC G01R 21/133

(57) ABSTRACT

A pass-through tag, such as an active radio frequency identification (RFID) device, provides power to a host device and measures the current used by the host device over a predetermined time period. The pass-through tag transmits the current usage of the host device to a remote server, which stores the current usage in a database. The server calculates at least one parameter for determining the usage state of the host device based on the stored current usage measurements. The remote server transmits the parameter(s) to the pass-through tag to enable the pass-through tag to determine the usage state of the host device.

### CROSS-REFERENCE TO RELATED APPLICATIONS

This application claims the benefit of U.S. Provisional Patent Application No. 62/003,547, “Usage State Detection Algorithms for inline AC-Powered RTLS Tags”, filed May 28, 2014 which is incorporated by reference herein in its entirety.

### FIELD OF THE INVENTION

The present disclosure relates to monitoring electrical power usage and, more specifically, to an integrated electrical pass-through connection between an electrical power source and an electrically powered host device.

### BACKGROUND OF THE INVENTION

In hospital settings, pass-through tags can be placed between the input electrical power connector on a host device (e.g., an infusion pump, ventilator, etc.) and an electrical power cable for the host device. This placement of the pass-through tag can automatically recharge the tag's battery whenever the host device is plugged into an electrical outlet, essentially removing the need to replace or recharge the battery. The pass-through tag can also monitor the current consumption of the host device to measure its power consumption.

### SUMMARY OF THE INVENTION

In one form, the present disclosure describes a pass-through tag that provides electrical power to a host device. The pass-through tag measures the current usage by the host device over a predetermined time period and transmits measurements of the current usage to a remote server. The pass-through tag receives at least one parameter from the remote server, which is used in determining the usage state of the host device.

In another form, the present disclosure describes the remote server that receives one or more current usage measurements of a host device from a pass-through tag associated with the host device. The server stores the current usage measurements in a database and calculates at least one parameter for determining a usage state of the host device. The server transmits the parameter(s) to the pass-through tag, enabling the pass-through tag to determine the usage state of the host device.

### BRIEF DESCRIPTION OF THE DRAWINGS

The foregoing and other features of the present disclosure will become apparent to those skilled in the art to which the present disclosure relates upon reading the following description with reference to the accompanying drawings.

FIG. 1 is a block diagram showing a system that can employ a pass-through tag between an electrical power source and an electrically powered host device (e.g., a medical equipment asset) in accordance with an example.

FIG. 2 is a schematic diagram of a pass-through tag that has a 3-wire alternating current (AC) pass-through connection and a cable connector (e.g., that can be utilized instead of a rigid connector) to interface with a host device in accordance with an example.

FIG. 3 is a network diagram showing the key components of a system of pass-through tags that can be used to provide usage state detection of the tags' associated AC-powered host devices in accordance with an example embodiment.

FIG. 4 is a flow chart showing how a plug-in measurement (PIM) of an AC-powered host device is captured on a pass-through tag and sent to a network server for storage in its Plug-in Measurement (PIM) Database.

FIG. 5 is a flow chart showing how a Device Characterization Measurement (DCM) is orchestrated by a smartphone app, performed on a host device by a pass-through tag, and then sent to a network server for storage in a DCM Database.

FIG. 6 is a flow chart showing how PIM snapshots and DCM Measurements are used to develop and/or update USD algorithms for an AC-powered host device and select parameters for those algorithms using data stored in PIM and DCM Databases for that host device.

FIG. 7 is a graph showing the current usage measured by a pass-through tag connected to a device as it is initially plugged in and starts up active operation.

FIG. 8 is a flow chart showing a procedure for developing a USD algorithm and selecting parameters for USD of a host device from DCM measurements.

FIG. 9 is a graph showing a plurality of current usage measurements showing the host device in various states of inactive/active operation.

FIG. 10 is a flow chart showing a procedure for developing a USD algorithm and selecting parameters for USD of a host device from PIM measurements.

FIG. 11 is a graph showing the probability density function (PDF) for the current consumed by the host device in various combinations of active/inactive and battery charging states.

FIG. 12 is a flow chart showing a procedure for selecting and updating USD detection thresholds in the USD database.

### DETAILED DESCRIPTION OF THE INVENTION

The present disclosure relates generally to an active radio frequency identification (RFID) device and, more specifically, to an active RFID device that supports an electrical pass-through connection between an associated host device and an electrical power source, and associated methods of use. In some instances, the pass-through connection may be used to monitor the power consumption of a host device. Additionally, the pass-through connection may be used to charge a battery of the RFID device. While the description below describes operation in a medical environment (e.g., a hospital), other facilities (e.g., factories, office buildings) may benefit from the system described herein to improve inventory control and utilization.

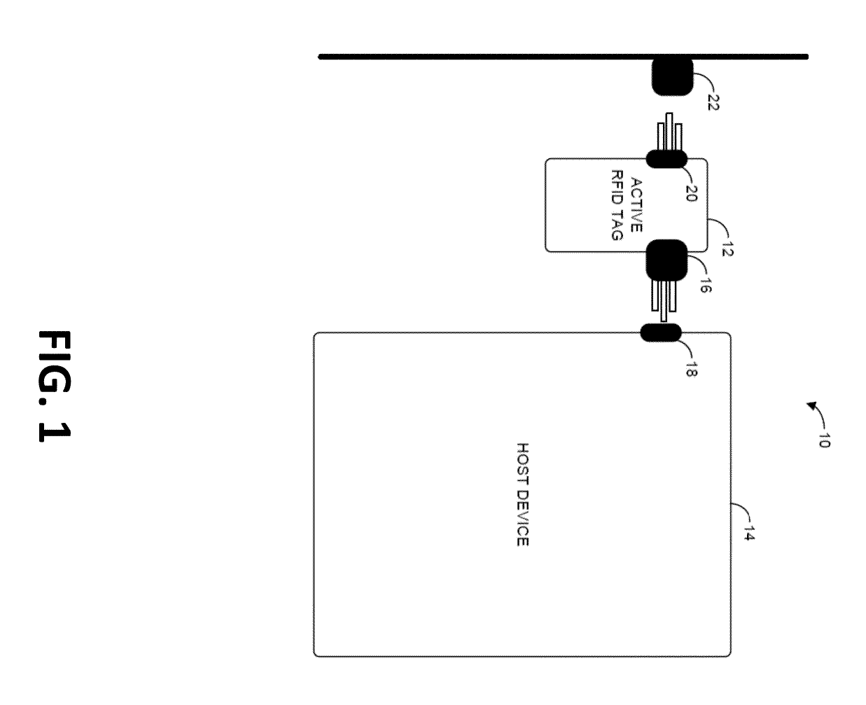

Active RFID tags are self-powered (e.g., via an internal battery) tags that can be attached to a host device such as an infusion pump, ventilator or hospital bed and transmit or receive wireless location beacon signals that can be used to determine the location of the tag. FIG. 1 illustrates an example of a system 10 employing an active RFID tag 12 that has an electrical pass-through connection between an external power source 22 and a host device 14. The external power source 22 is typically an AC power mains. The active RFID device 12, also referred to herein as a “pass-through tag”, can interface with the external power source 22 through an input power connector 20 and with the host device 14 through an output power connector 16, where both input and output power connectors are positioned on the exterior of the RFID device. The input and output connectors are electrically connected using a “pass-through” connection inside the device 12.

The pass-through tag 12 can, through its output power connector 16, interface with a power input port 18 (e.g., an IEC 60320 C14 AC power inlet, barrel DC connector, USB connector, or other power input port) of the host device 14. Although the output power connector 16 is illustrated in FIG. 1 as a male connector and the power input port 18 is illustrated as a female connector, it will be appreciated that other types of connections and/or interfaces can exist between the output power connector 16 and the power input port 18. For example, the male and female components can be reversed (e.g., the power input port 18 can include a plug that can interface with the output power connector 16). In another example, a different type of output power connector 16 can be used that corresponds to the configuration of the power input port 18 (e.g., a USB connection and a USB port, a serial connection and a serial port, etc.).

The pass-through tag 12 can also, through its input power connector 20, interface with an external power source 22. The external power source 22 may be an AC power mains, line power source, an emergency generator, DC power supply or other power source external to the pass-through tag 12. Although the input power connector 20 is illustrated as a male connector and the external power source 22 is illustrated as a female connector, it will be appreciated that other types of connections and/or interfaces can exist between the input power connector 20 and the external power source 22. For example, the male and female components can be reversed (e.g., the external power source 22 can include a plug that can interface with the input power connector 20).

Thus, as depicted in FIG. 1, the output power connector 16 can supply an output electrical power signal based on the input electrical signal received by the input power connector 20. The input electrical power signal may include an alternating-current signal. In another form, the input electrical power signal may include a direct-current signal and the output electrical power signal may comprise a direct-current signal.

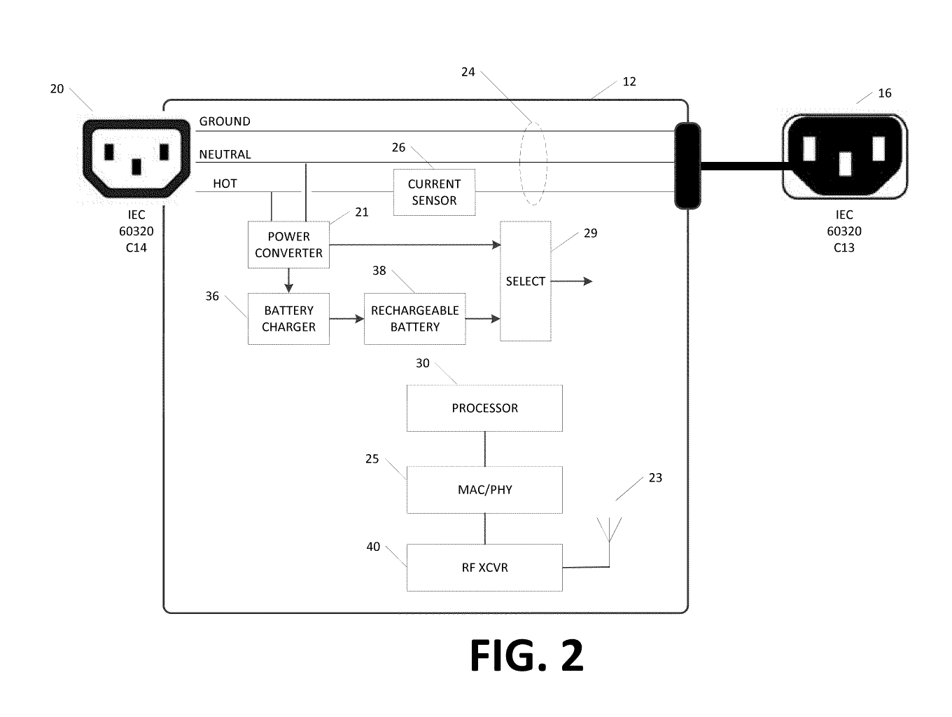

Referring to FIG. 2, the pass-through tag 12 may contain a wireless access control/physical layer (MAC/PHY) processor 25 and a RF transceiver 40. The RF transceiver can send and receive RF signals through an antenna 23 than may be positioned inside or outside the tag 12. The MAC/PHY processor 25 and RF transceiver 40 may be used to exchange current usage measurements with one or more remote servers. The MAC/PHY processor 25 and RF transceiver 20 may operate in accordance with a wireless standard such as IEEE 802.11/Wi-Fi®, Bluetooth®, Bluetooth Low Energy, or IEEE 802.15.4 Zigbee to communicate with the remote server through wireless access points. Alternatively, the pass-through tag 12 may communicate through wired communication means, such as power line communication through the AC mains power connector 20.

Additionally, the pass-through tag 12 may include a processor 30 with an associated memory 31 for storing executable instructions and data. It is to be understood that the memory 31 may be present in the various examples of the tag 12 presented herein, but for simplicity, it is not shown again in the subsequent figures. The processor 30 is configured to execute the executable instructions to, among other things, determine a usage state of the host device using the measurement obtained by a current sensor 26. The processor 30 may encode the measurement obtained by the current sensor 26 into a data packet for transmission by the wireless transceiver 40.

The output of the current sensor 26 may be used to determine a usage state of the host device. This is because a host device generally consumes a different amount of electrical current in each of its usage states. For example, a medical device such as an infusion pump will consume zero electrical current from its AC input power port when it is unplugged from an AC power source. The medical device will consume a small amount of AC current when plugged into the AC power source but powered off; more current when it is plugged in, powered on and idle; and even more current when plugged in, powered on and actively being used. Each host device generally consumes a measurably different amount of current in each of its usage states (e.g., actively administering a medication, idle waiting to be programmed, diagnostics mode, etc.), and there is usually a one-to-one correspondence between the amount of current being consumed and its usage state. The mapping of current consumption to usage state generally varies as a function of device type, manufacturer and model number. This mapping information could be measured for each unique combination of device type, manufacturer and model number and stored in a database. A pass-through tag could look up the mapping information for its associated host device from such a database, store it internally in a non-volatile memory, and use this information along with current consumption measurements to determine the usage state of the host device.

The memory 31 can include read only memory (ROM), random access memory (RAM), magnetic disk storage media devices, optical storage media devices, flash memory devices, electrical, optical, and/or other physical/tangible/non-transitory memory storage devices. Thus, in general, the memory 31 may comprise one or more tangible (non-transitory) computer readable storage media (e.g., a memory device) encoded with software comprising computer executable instructions and when the software is executed (e.g., by the processor 30) it is operable to perform various operations described herein.

The tag 12 may further contain a battery charger 36 that charges a rechargeable battery 38 whenever the host device is plugged into an AC mains, and a current sensor 26 that monitors the electrical current flowing from the power source 22 to the host device 14. A power converter 21 converts electrical power from the AC mains through power connector 20 to power the battery charger 36 and/or the remainder of the tag 12 through the power selection logic 29. The power selection logic 29 may select the power source of the tag 12 based on the state of the rechargeable battery 38 and whether the power converter 21 can supply the electrical power from the AC mains.

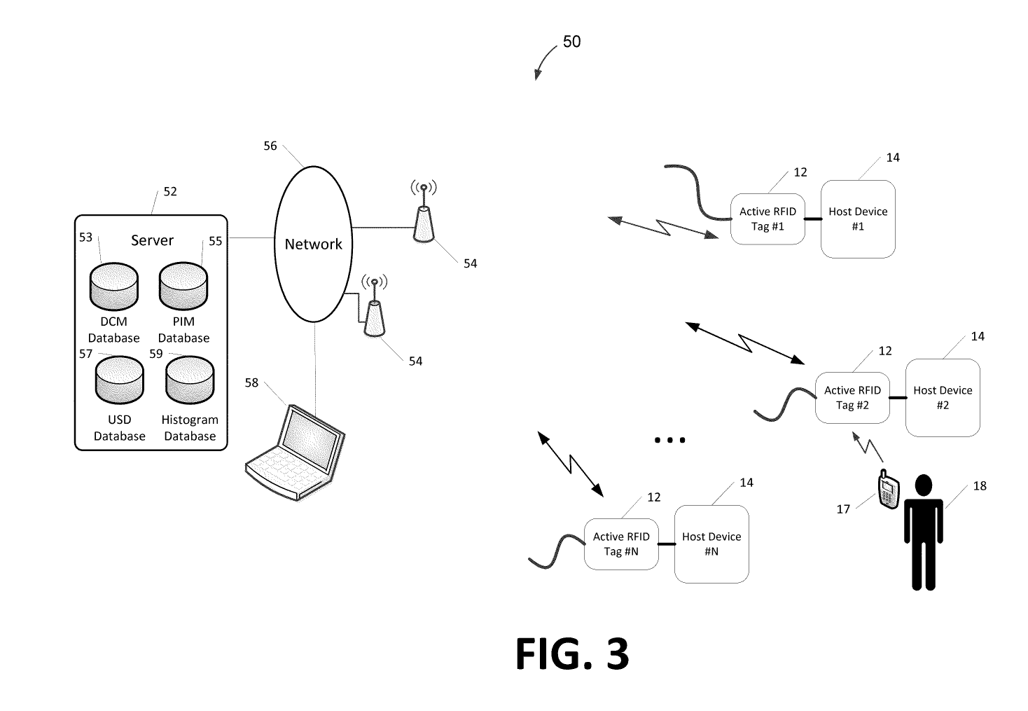

FIG. 3 illustrates an example of a system 50 employing one or more pass-through tags 12 communicating with a server 52 via a wireless network connection. Each tag is attached via an AC power cable to host device 14. Server 52 is responsible for configuring the tags 12 and storing in a database the type, make, model number and serial number (e.g., a unique identifier) of the host devices to which they are attached. Server 52 also stores Plug-in Measurements (PIMs) storing digital samples of the RMS current consumed by host devices 14 for an initial time period (e.g., 30 seconds) after they are plugged into AC power. The PIM measurements are stored in a PIM Database 55 on the server. Server 52 also stores Device Characterization Measurements (DCMs) that may be collected by a smartphone or tablet application 17 that communicate with the tags 12 via a Bluetooth Low Energy (or similar) connection. Further, Server 52 maintains a Usage State Detection (USD) Database 57 storing computer instructions and algorithm parameters for USD algorithms that run on the tags. Additionally, Server 52 maintains a Histogram Database 59 storing histogram data for current usage by host devices 14, and measured by the associated tags 12 over a long period of time. Each of the databases 53, 55, 57, and 59 may be implemented as a separate database or one or more of the databases may be combined into a single database.

In one example, the tags 12 communicate with Server 52 through one or more wireless Access Points (APs) 54 using a wireless internet signaling protocol such as IEEE 802.11 Wi-Fi. The Server 52 and wireless APs 54 may be coupled through network infrastructure 56 that also connects to one or more other user devices 58. The access points 54, tags 12 and host devices 14 that communicate with Server 52 may reside in different hospitals, buildings, and/or networks.

In another example, the PIM database 55 stores PIM measurements comprising digital recordings of the current consumption of a host device 14 for an initial time period, such as 30 seconds, after the tag 12 and host device 14 are plugged into AC power. The PIM measurements may be useful because most medical devices have internal batteries in case there is an interruption of AC power, and the host devices 14 will typically start charging their internal batteries 5-15 seconds after they are plugged in.

Based on the PIM measurements stored in the PIM database 55, the server may determine whether the device is charging its battery and if so, what portion of the measured current consumption is due to the battery charging. Further, a user accessing the server may determine what the waveform looks like when the battery is charging. Alternatively, an algorithm running on the server may characterize the waveform data of the current usage due to the battery charging. The initial battery charging current and waveform enable the server 52 to determine whether a device is consuming current because it is actively being used or because the internal battery is being charged.

Using the PIM database 55, the Server 52 may use a unique identifier or combination of non-unique identifiers (e.g., the type, make and model number of a host device) to return all of the PIM snapshots that have been taken for that host device. In one example, the non-unique identifier(s) may enable data from multiple identical (i.e., the same type, make and model number) devices to be analyzed together. This information can then be used (either by a user looking at this information manually and doing analysis, or via some automated procedure, or a combination of automatic and manual analysis) to derive an algorithm and/or algorithm code and/or parameters that can be used to determine a usage state of the host device.

In a further example, the algorithm code and/or parameters to determine the usage state of the host device may be stored in the USD database 57. Given the unique identifier of a host device, the USD database 57 may produce some computer code (e.g., to implement a USD algorithm) that can run on the tag processor 30 and/or some data parameters (e.g., thresholds, constants) that can be used to determine a usage state of the host device 14—in particular, whether that device 14 is actively being used.

Additionally, the algorithm code may be pre-stored in the memory on the tags and only parameters are obtained from the server 52. In some cases, new algorithm code may be required for a tag 12, e.g., to identify a new host device 14 that just came out in the market and may behave slightly differently from other host devices 14 of the same type.

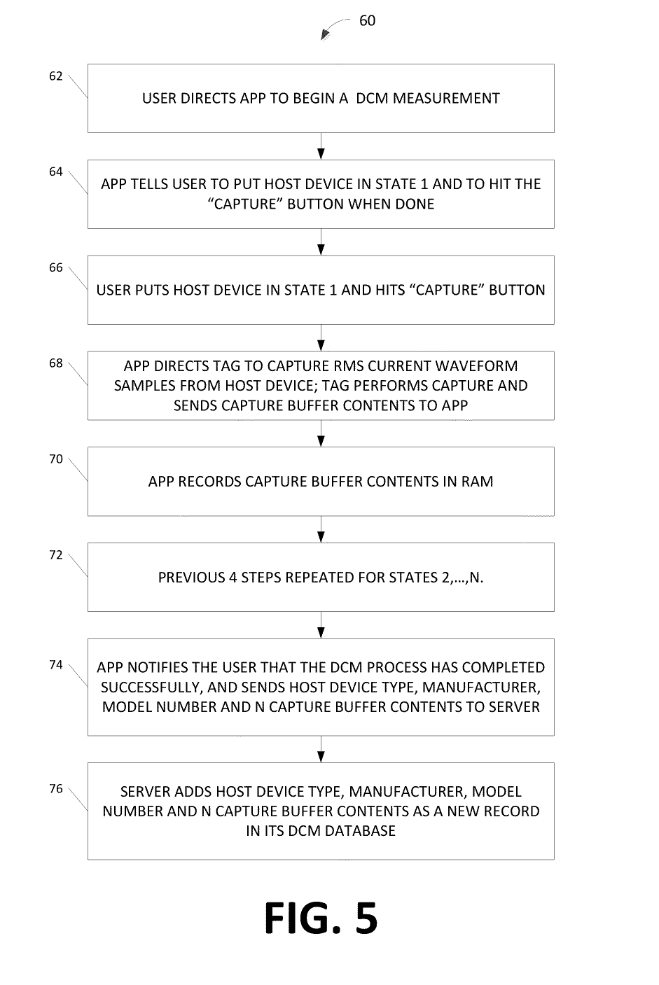

In yet another example, the Device Characterization Measurement (DCM) Database 53 stores DCMs taken from tags 12 for their host devices 14. The DCM capture process may be an interactive one involving a user 18, the tag 12, the host device 14 and the smartphone or tablet app 17 that communicates with the tag 12 via a Bluetooth Low Energy (BLE) connection. The procedure is described in detail in flowchart 60 in FIG. 5.

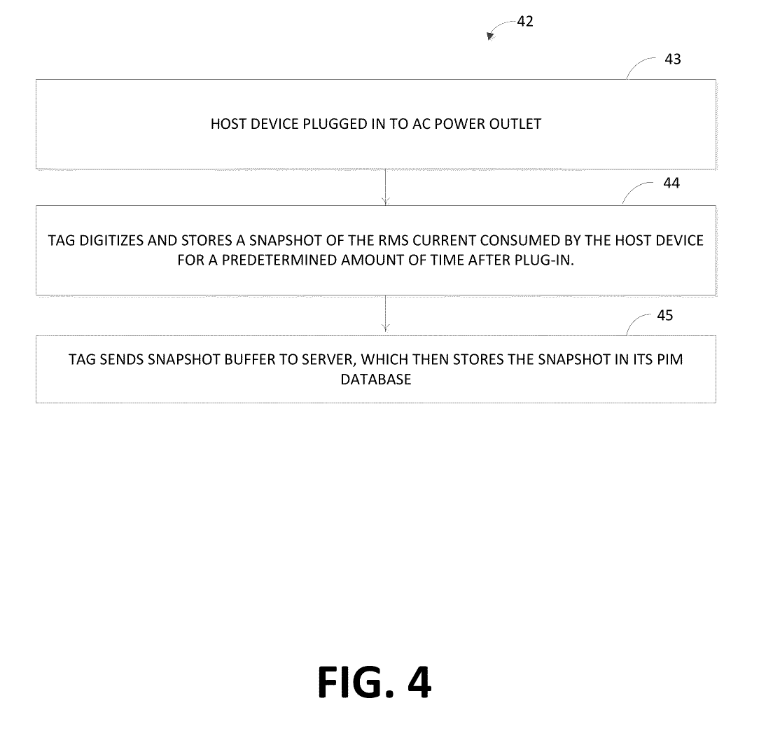

Referring now to FIG. 4, a procedure 42 is shown for recording a PIM when a host device 14 and pass-through tag 12 is initially powered on. The tag 12 may be configured to record a PIM “snapshot” every time the host device 14 is plugged into AC power. In step 43, the host device 14 is plugged in to an AC power outlet through the pass-through tag 12. After the plug-in happens, the tag power converter 21 generates an interrupt to the tag processor 30. In step 44, the tag processor 30 starts sampling the output of the current sensor 26 for a predetermined period of time. In one example, the current is sampled at a rate of 100 samples per second using an analog-to-digital converter and the samples are stored in a buffer in the CPU memory. In step 45, the snapshot buffer (˜100 samples/second*30 seconds=3000 samples) is uploaded from the tag to the server 52 and stored in its PIM database 55.

Referring now to FIG. 5, a procedure 60 for collecting current measurements in specified usage states is shown. In step 62, a user with a mobile device, such as a smart phone or tablet, starts a user application to coordinate the DCM measurement. In step 64, the mobile device instructs the user to put the host device in a first specified state and press a “capture” button on the application. In step 66, the user puts the host in the first specified state (e.g., powered on and inactive and not charging the battery) and presses the “capture” button on the user application of the mobile device.

In step 68, the user application communicates with the tag 12 (e.g., via Bluetooth) and direct the tag 12 to capture the RMS current waveform supplied to the host device 14. The tag 12 samples the current using predetermined settings (e.g., sampling rate, number of samples, time period, etc.) and transmits the capture buffer contents to the user application in the mobile device. The user application records the capture buffer contents into the memory of the mobile device in step 70. In step 72, the user application cycles through steps 64, 66, 68, and 70 for each of the other possible states of the host device 14. Other states may include active operation performing various tasks, trickle charging the internal battery of the device 14, full charging of the internal battery, and/or a combination of active/inactive states and battery charging states.

After current measurements have been made and stored on the user's mobile device the user application notifies the user that the DCM process has completed successfully in step 74. The user application sends the capture buffer contents for each state along with a unique identifier of the host device to the server 52 to store in the DCM database 53. In step 76, the server adds a new record in the DCM database 53 comprising the unique identifier of the host device 14 and the capture buffer contents of current usage in each of the specified states of the host device 14.

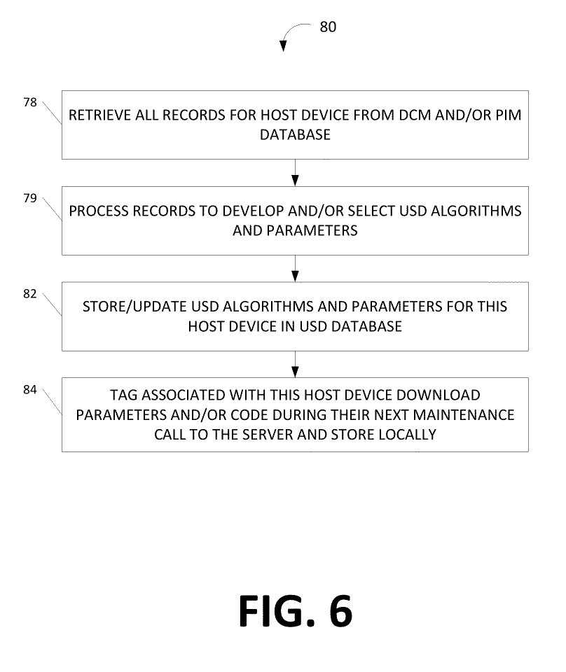

Referring now to FIG. 6, a procedure 80 of processing PIM and/or DCM data to develop a USD algorithm and/or parameters for USD algorithms is shown. The procedure may be performed either automatically (e.g., in server 52) or manually (e.g., by a user using server 52) or a combination of both. In step 78, a unique identifier for a host device 14 is used to retrieve all of the records for the host device 14 from the DCM database and/or the PIM database. In step 79, the retrieved records are processed to develop and/or select USD algorithms and parameters. In step 82, the USD algorithms and parameters for the host device 14 are stored in the USD database on the server 52. In one example, the record in the USD database associated with the host device 14 may already exist, in which case, the algorithm and/or parameters are updated to reflect any additional PIM/DCM data received since the original USD algorithm and parameters were developed for that host device 14. In step 84, the tag 12 associated with the host device 14 downloads from the server 52 the parameters and/or code for the algorithm during their next maintenance call to the server. The parameters and code for the algorithm are stored locally on the tag and may be used by the tag 12 to determine the usage state of the host device 14.

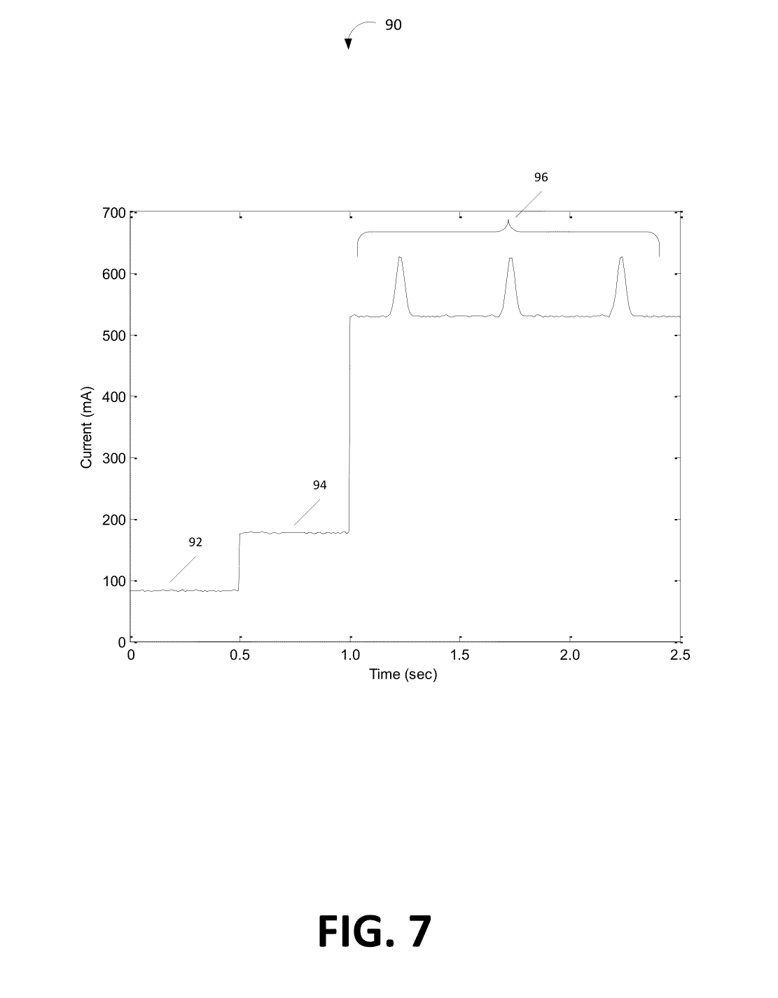

Referring now to FIG. 7, a graph shows an example of a PIM 90 captured when a host device 14 is initially plugged in. The device 14 is plugged in through pass-through tag 12 at a time t=0 seconds, and draws a small but constant amount of current for 0.5 seconds while the device 14 boots up in an inactive state 92. The device 14 draws a different, but still relatively constant, amount of current for another 0.5 seconds while in state 94, which is an inactive operational state but charging its internal battery. After the device 14 goes into an active operational state 96, the device 14 draws a higher and time varying amount of current with 100 mA spikes in current every 0.5 seconds.

The periodic nature of these 100 mA spikes in current is typical of many medical devices that are powering sensors, servos or small motors to perform an action for a patient. A respirator, for example, exhibits current spikes every 1-5 seconds while “breathing” for a patient. Some hospital beds periodically turn on fans to blow air into a part of the mattress to prevent patients from developing blood clots. When the host device is only charging its battery on the other hand, the current consumption, although sometimes significant, is mostly constant. These facts can be exploited by a USD algorithm to determine whether a host device is actively being used. For example, to determine whether a respirator is operationally active, one could calculate a peak-to-average ratio or standard deviation of the RMS current signal over the past several seconds. If either of these metrics exceeds an appropriate threshold, the USD algorithm would conclude that the respirator was actively being used.

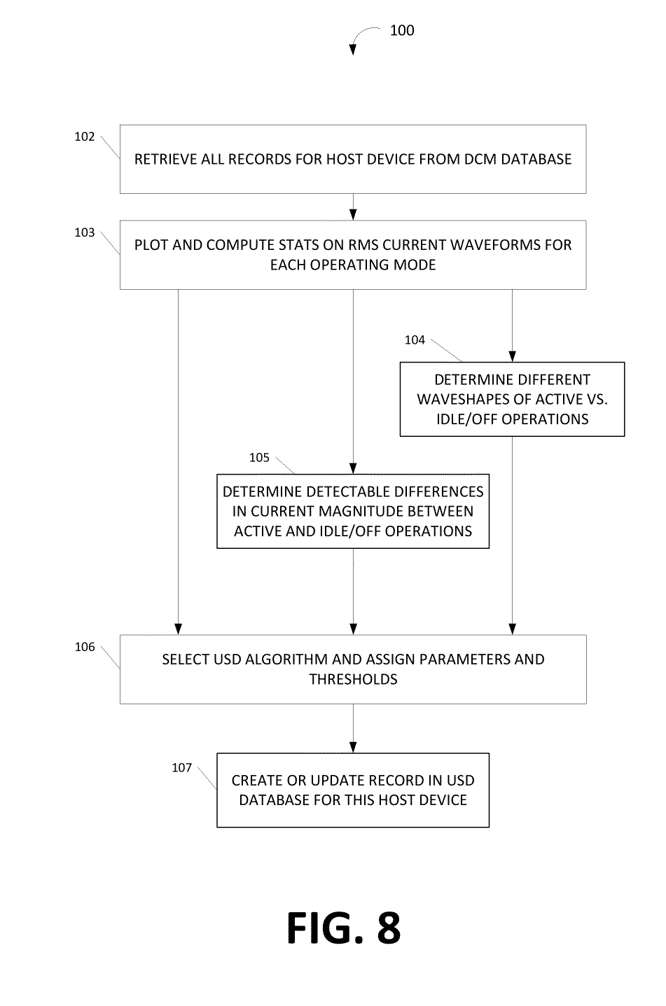

Referring now to FIG. 8, a procedure 100 for selecting a USD algorithm and/or assigning appropriate parameters for a specific host device is shown. The procedure 100 may be performed manually by a user accessing server 52, automatically by an algorithm running on a processor, or some combination of manually and automatically performed steps. In step 102, the server 52 retrieves all of the records for a specific host device 14 from the DCM database 53. The current usage measurements from the DCM database records are plotted and various statistical measures are calculated in step 103. In one example, plotting each of the DCM records of current usage on the same graph allows commonalities and differences in the waveforms to become apparent. In another example, the statistical measures may include a peak-to-average current ratio or a standard deviation over some/all of each of the captured waveforms. In a further example, a fast Fourier transform (FFT) of the various waveforms may be computed to compare the spectral content in various operating modes.

In step 104, the waveforms of the current usage are compared to determine if there are differences between the waveforms of the device in active operational mode and an inactive operational mode. For example, as seen in FIG. 7, the 100 mA spikes shown during the active operational mode 96 would create a waveform with noticeably different statistical measures from the relatively flat waveform shown for the device in inactive operational states 92 or 94. In step 105, the magnitudes of the current usage measurements are compared to determine if there is a noticeable difference between active operation and idle/off/battery charging modes of operation. Again referring to FIG. 7, the average magnitude of the current in the active operational state 96 is significantly higher than either the battery charging state 94 or the idle state 92.

In step 106, a USD algorithm specific to the host device 14 is selected based on the current usage waveforms in the DCM database for the host device 14. Parameters/thresholds for the USD algorithm may also be assigned based on the analysis of the DCM records. In step 107, the record for the host device 14 in the USD database 57 is updated, or created if one does not exist. The USD algorithm and the assigned parameters combine to enable a pass-through tag to accurately determine the state of the user device 14 based on a subsequent measurement of current usage.

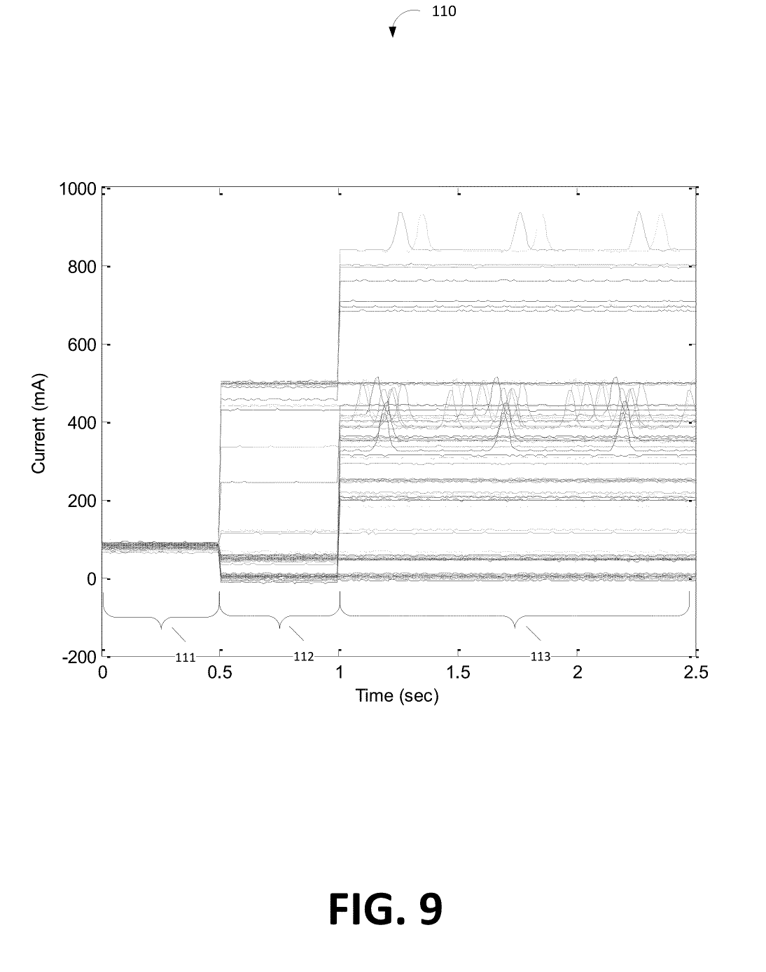

Many host devices charge their batteries for a short period of time after boot-up before going into an operational state, even if their power buttons were switched on immediately after plug-in. This fact may be exploited by a USD algorithm to assign known states to current usage measurements made immediately after plug-in. For example, FIG. 9 shows a graph 110 of one hundred PIM captures from a device 14 that always charges its internal battery for at least 0.5 seconds after plug-in. Initially, the device 14 always draws approximately the same current in each of the captures while the device 14 boots up in time period 111. In time period 112, the device 14 draws a constant amount of current as it charges its internal battery. Though the amount of current for each PIM capture is constant, the actual amount of current drawn varies between PIM captures, e.g., based on the charge in the battery. In time period 113, the device 14 draws current based on several different operational modes, including active operation (e.g., with periodic current spikes) and inactive modes (e.g., where the current is unchanged from the battery charging states from time period 112).

In one example, the current usage measurements may be normalized before being compared to correct for inconsistencies in measurement (e.g., by different tags). The current measurements may be normalized to the current consumption in a known state, such as the current measured in time period 111, right after the device 14 has been plugged in. Alternatively, the normalization algorithm may be based on one or more other known operating states.

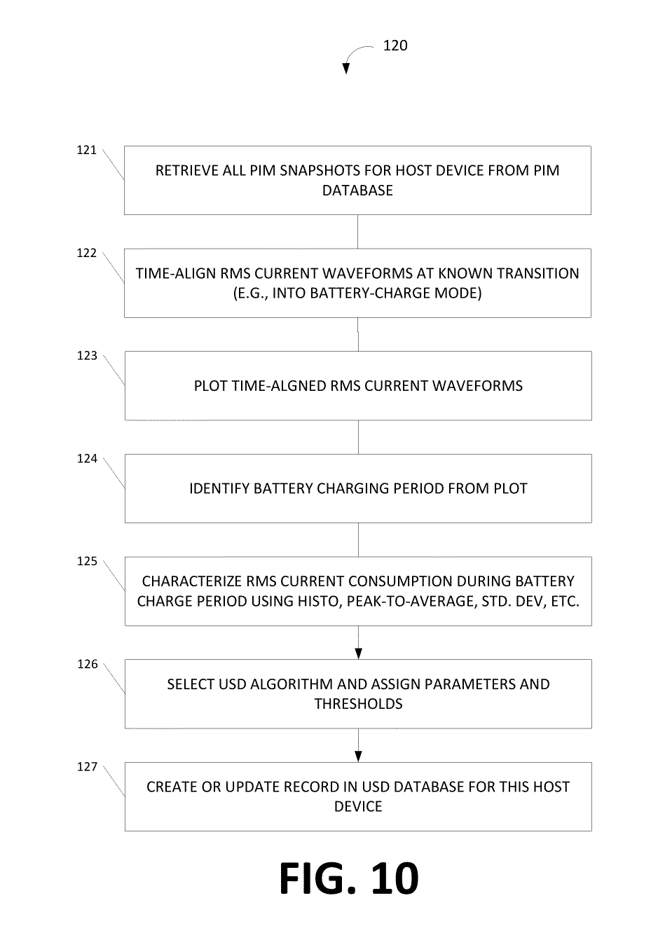

Referring now to FIG. 10, a procedure 120 for selecting a USD algorithm and assigning parameters/thresholds based on PIM captures is shown. In step 121, all of the PIM records for a specific host device 14 are retrieved from the PIM database 55. In step 122, the PIM records are aligned in time to a known transition, such as the transition from boot-up mode to the battery charging mode. The time-aligned current waveforms are plotted in step 123, and the battery charging period (e.g., time period 112 in FIG. 9) is identified in step 124. The RMS current consumption of the device 14 during the battery charging period is characterized through various statistical methods (e.g., histogram, peak-to-average ratio, standard deviation, etc.) in step 125. In step 126, the USD algorithm is selected and parameters/thresholds for the algorithm are assigned based on the various statistical measures of the time-aligned PIM current waveforms. In step 127, the record in the USD database 57 for the host device 14 is updated (or created, if one does not already exist) with the selected USD algorithm and parameters/thresholds.

In one example, selecting a USD algorithm and parameters based on the PIM records (as shown in FIG. 10) instead of the DCM records (as shown in FIG. 8) may provide an advantage in that the PIM data is gathered automatically every time the device is plugged in. The DCM data is gathered manually via user interaction, so there may be fewer data records to provide a statistical sample of the operating modes. Additionally, the DCM is subject to user error, such as putting the user device 14 in the wrong operating state indicated by the user application. However, the PIM data may not encompass every possible operating state, since the device may not enter every state within the initial time period after startup. In some instances, a combination of PIM data and DCM may be used to provide an accurate USD algorithm for all of the operating states of a host device 14.

In a healthcare setting, most AC-powered host devices have an internal rechargeable battery that is often used, for example, when moving the device with a patient from one room to another. From an AC current consumption perspective, the overall state of the host device depends on two independent sub-states: the battery charging state and the operating state. The battery charging state may be either off (i.e., not charging), which uses almost zero current; trickle charging, which typically uses a relatively small amount of current to “top off” an almost fully-charged battery; fully charging, which typically uses 10-20 times more current than when trickle charging; or something in between trickle charging and fully charging. The operating state of the host device may be either powered off, which often consumes a small but non-zero amount of current; inactive, which is powered on, but not performing any functions; or one of several active operational states in which the device is performing one or more functions. The total current consumed by the host device is the sum of the current consumed in each of the two sub-states.

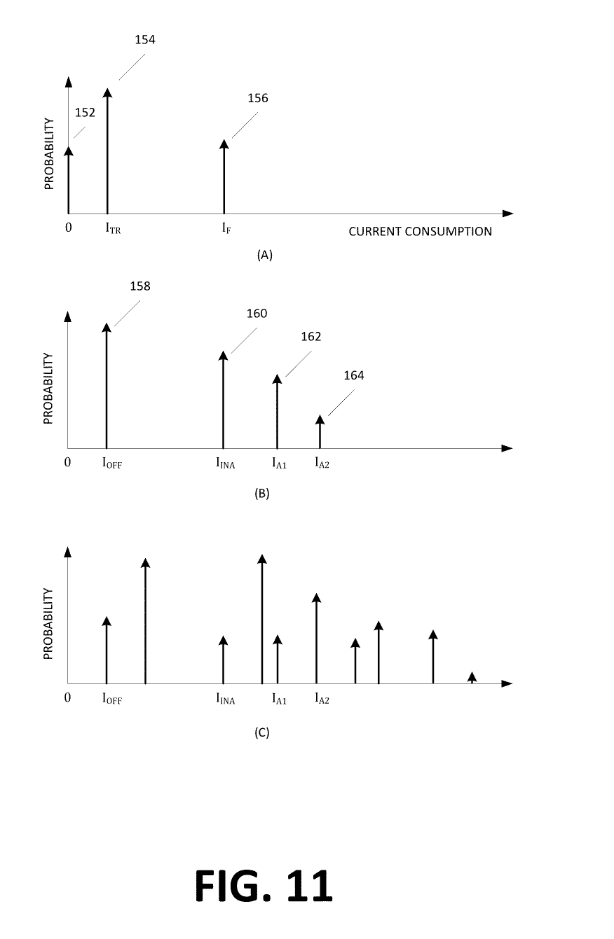

Referring now to FIG. 11, the probability density functions (PDFs) for the current consumed in various states and sub-states of a host device are shown. FIG. 11A shows the PDF for the RMS current consumed by the battery charger for an example host device. The battery charger state in this example takes on one of three states: an off state 152 (zero current), a trickle charge state 154, and a full charge state 156. FIG. 11 B shows the PDF for the operational states of the same host device. There are four operational states: an off state 158, an inactive state 160, a first active state 162, and a second active state 164. FIG. 11C shows the PDF for the total current consumption of the example host device. Since the total current is the sum of the battery charger and operational state current consumptions, the PDF for the total current is the convolution of the PDFs for the battery charger and operational state contributions. This leads to substantially more impulses in the PDF of the overall current consumption.

Recognizing that the PDF of the overall current consumption of a host device may be written as the convolution of the battery charger and operational state PDFs can lead to a simplification in the way USD algorithms are developed and parameterized using DCM and PIM information.

In one example, one or more tags 12 may track the current consumed by its host device 14 over long periods of time using a histogram. The tags may periodically upload these histograms to the server 52 and store them in the histogram database 59.

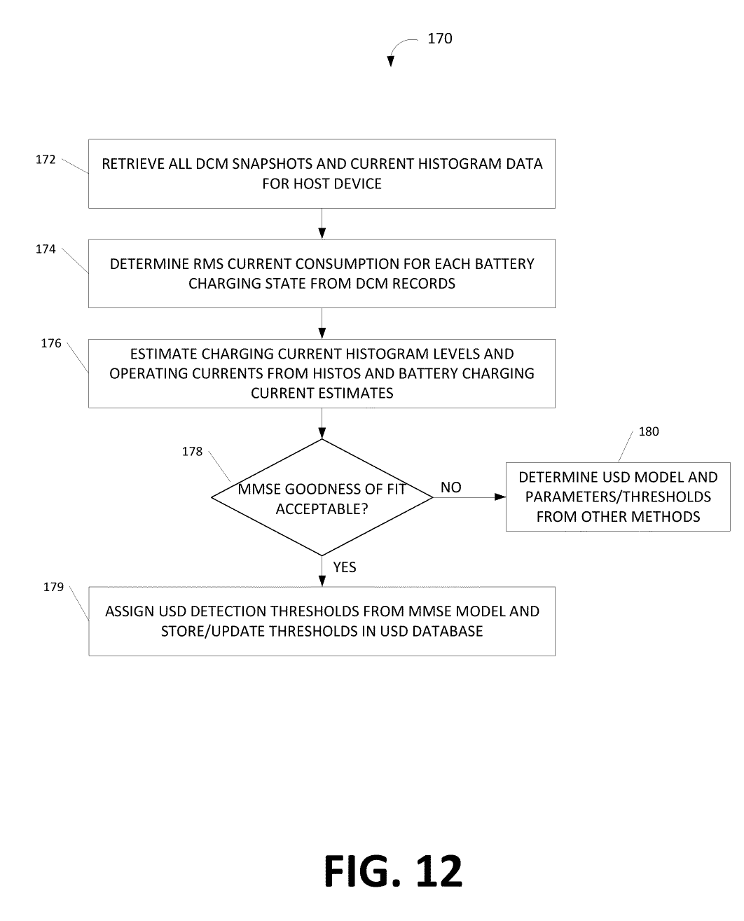

Referring now to FIG. 12, a procedure 170 for developing and parameterizing a USD algorithm from the deconvolution of battery charging sub-sates and operational sub-states is shown. In step 172, all of the DCM records for a host device are retrieved from the DCM database 53 for a user-specified host device type, manufacturer and model number. Additionally, the histogram records for the device are also retrieved from the histogram database. In step 174, the PDF for the battery charging states is determined from the DCM measurements and recorded as a vector P_{b} of discrete probabilities. In step 176, the retrieved histogram data for the overall current consumption by the host device is used to determine the PDF for the overall current, i.e., the sum of the operational and battery-charger current, which is stored as a vector Pₒᵥ. Since the vector Pₒᵥ can be written as the convolution of P_{b} and Pₒₚ, which is the PDF of the operational states, an estimate of Pₒₚ can be made from P_{b} and Pₒᵥ using one of any known deconvolution methods, such as polynomial division, minimum mean square error (MMSE), etc.

If the goodness of fit of the estimated Pₒₚ is acceptable, as determined in 178, then the USD detection thresholds from the Pₒₚ may be used to determine threshold in the USD algorithm in step 179. If the fit is not good, i.e., the battery charging states and the operating states are not easily separated by deconvolution, then the USD algorithm is determined as described above with respect to FIGS. 8 and/or 10.

In one example, determining parameters by deconvolution of the battery charging states and the operational states dramatically simplifies the DCM measurement process, since the user needs to only characterize the device in its battery charging states with the power turned off. Without this approach, the user would have to characterize the device for all unique combinations of battery charger and operational state, so the new approach reduces the number of DCM measurements from N*M to N, where N is the number of battery charging states and M is the number of operational states for the host device. Removing the need for the user to accurately place the host device in various operating states lowers the number of opportunities for human error to corrupt the DCM data. Alternatively, the user may measure the current for all of the operational states at a fixed battery charger state, enabling a calculation of Pₒₚ. In this case, P_{b} may be estimated by deconvolution instead of Pₒₚ. Another optimization of the above procedure involves measuring the PDF of the battery charger current using PIM measurements instead of DCM measurements. The key advantage of this approach is that no DCM measurements are required, so the USD algorithm and/or parameters can be determined automatically from the PIM and DCM measurements without any human involvement. A disadvantage is that for some host devices it may be very difficult to extract the battery charger current from the PIM data.

In summary, the techniques presented herein provide for a pass-through tag that measures the current usage of a host device and communicates with a remote server to store the current usage measurements. The records of the current usage measurements are used to determine an algorithm and parameters/thresholds for the algorithm to determine the usage state of a host device based on a subsequent current usage measurement. Determining the usage state of individual host devices allows for automated inventory control, e.g., in large hospital settings, and more efficient utilization of host devices.

From the above description, those skilled in the art will perceive improvements, changes and modifications. Such improvements, changes and modifications are within the skill of one in the art and are intended to be covered by the appended claims.

What is claimed is:

1. A method comprising:
providing electrical power from a pass-through tag to a host device;
in the pass-through tag, measuring a current usage by the host device over a predetermined time period;
transmitting the measured current usage to a server; and
receiving from the server, at least one parameter for determining a usage state of the host device.

2. The method of claim 1, further comprising:
determining the usage state of the host device based on the at least one parameter received from the server; and
transmitting the usage state of the host device to the server.

3. The method of claim 1, wherein the predetermined time period includes an initial power up of the host device.

4. The method of claim 1, further comprising:
receiving a notification of a test sequence in which the host device is placed in one or more specified usage states; and
measuring the current usage of the host device while the host device is in each of the one or more specified usage states.

5. The method of claim 4, further comprising transmitting to the server, the measured current usage of the host device in each of the one or more specified usage states.

6. The method of claim 1, further comprising transmitting to the server, one or more identifiers of the host device associated with the measured current usage.

7. The method of claim 1, wherein the at least one parameter includes one of a threshold for a peak-to-average ratio of the measured current usage, a threshold for a standard deviation of the measured current usage, or a threshold for a Fast Fourier Transform (FFT) of the measured current usage.

8. A method comprising:
receiving from a pass-through tag, one or more current usage measurements of a host device;
storing the current usage measurements in a database;
calculating at least one parameter for determining a usage state of the host device based on the stored current usage measurements in the database; and
transmitting the at least one parameter to the pass-through tag.

9. The method of claim 8, further comprising receiving an indication of the usage state of the host device, the usage state being determined based on the at least one parameter.

10. The method of claim 8, wherein the received current usage measurement includes a measurement of current usage by the host device over a predetermined time period.

11. The method of claim 10, wherein the predetermined time period includes an initial power up of the host device.

12. The method of claim 10, wherein the measurement of current usage by the host device over the predetermined time period includes an indication that the host device was in a specified usage state during the predetermined time period.

13. The method of claim 8, wherein calculating the at least one parameter includes calculating one of a threshold for a peak-to-average-ratio of a subsequent current usage measurement, a threshold for a standard deviation of the subsequent current usage measurement, or a threshold for a Fast Fourier Transform (FFT) of a subsequent current usage measurement.

14. The method of claim 8, further comprising receiving one or more identifiers of the host device associated with the received current usage measurement.

15. A system comprising:
a pass-through tag configured to:
provide electrical power to a host device;
measure a current usage by the host device over a predetermined time period;
transmit the current usage measurement to a remote server; and
receive from the remote server, at least one parameter for determining a usage state of the host device; and
the remote server configured to:
receive the current usage measurement from the pass-through tag;
store the current usage measurement in a database;
calculate the at least one parameter for determining the usage state of the host device based on stored current usage measurements in the database; and
transmit the at least one parameter to the pass-through tag.

16. The system of claim 15, wherein the pass-through tag is further configured to:
determine the usage state of the host device based on the at least one parameter received from the remote server; and
transmit the usage state of the host device to the remote server.

17. The system of claim 15, wherein the pass-through tag is further configured to:
receive a notification of a test sequence in which the host device is placed in one or more specified usage states; and
measure the current usage of the host device while the host device is in each of the one or more specified usage states.

18. The system of claim 17, wherein the pass-through tag is further configured to transmit to the remote server, the measured current usage of the host device in each of the one or more specified usage states.

19. The system of claim 15, wherein the pass-through device is further configured to transmit to the remote server, one or more identifiers of the host device associated with the current usage measurement.

20. The system of claim 15, wherein the pass-through tag and the remote server communicate through a wireless network connection.
